(19) United States
(12) Patent Application Publication
(10) Pub. No.: US 2019/0044323 A1
(43) Pub. Date: Feb. 7, 2019

(54) DEVICES AND METHODS FOR DE-ENERGIZING A PHOTOVOLTAIC SYSTEM

(71) Applicant: Alliance for Sustainable Energy, LLC

(72) Inventor: Christopher Alan DELINE, Golden, CO (US)

(21) Appl. No.: 15/759,599

(22) PCT Filed: Sep. 9, 2016
(86) PCT No.: PCT/US16/50927

§ 371 Date: Mar. 13, 2018

Related U.S. Application Data
(60) Provisional application No. 62/218,104, filed on Sep. 14, 2015.

(51) Int. Cl. H02H 7/20; H02S 50/10; H02S 40/36; H01L 31/02; H02J 3/38; H02S 40/32; H02H 1/00

(52) U.S. Cl. CPC H02H 7/20; H02S 50/10; H02S 40/36; H02H 1/0007; H02J 3/383; H02S 40/32; H01L 31/02021

(57) ABSTRACT

Devices and methods for de-energizing a photovoltaic (PV) system are provided. According to an aspect of the invention, a method includes detecting a resistance between a first photovoltaic unit and ground, wherein the first photovoltaic unit is connected to at least one additional photovoltaic unit. If the resistance is less than a threshold, the first photovoltaic unit is shorted by connecting a positive conductor of the first photovoltaic unit with a negative conductor of the first photovoltaic unit. Shorting the first photovoltaic unit causes the at least one additional photovoltaic unit to detect the resistance that is less than the threshold, thereby shorting the at least one additional photovoltaic unit by connecting a positive conductor of the at least one additional photovoltaic unit with a negative conductor of the at least one additional photovoltaic unit.

### CROSS-REFERENCE TO RELATED APPLICATIONS

This application claims priority under 35 U.S.C. § 371 to PCT/US16/050927, filed Sep. 9, 2016, which claims priority under 35 U.S.C. § 119 to U.S. Provisional Patent Application No. 62/218,104, filed on Sep. 14, 2015, the contents of both of which are hereby incorporated by reference in their entirety.

### CONTRACTUAL ORIGIN

The United States Government has rights in this invention under Contract No. DE-AC36-08GO28308 between the United States Department of Energy and Alliance for Sustainable Energy, LLC, the Manager and Operator of the National Renewable Energy Laboratory.

### BACKGROUND

The present invention relates to devices and methods for de-energizing a photovoltaic (PV) system. These devices and methods may be used in the event of an emergency. For example, if a building having a rooftop PV system catches fire, firefighters must find a way to shut down the PV system before they enter the building. Because the PV system continuously converts light to electricity, the PV system cannot be shut down simply by disconnecting the breaker. Even if the alternating current (AC) is shut down past the inverter, the direct current (DC) circuit between the PV modules and the inverter will still be live. This is particularly problematic if there is structural damage to the house or the circuit. For example, live wires may be in contact with additional conductive surfaces (e.g., metal supports and pooled water), which pose significant hazards to firefighters.

To address this problem, firefighters often shut down a PV system by hauling tarps up to the roof of the building and placing them over the PV modules to block incident light. This technique is both time-consuming and dangerous. Accordingly, it would be advantageous to provide a method of de-energizing a PV system that is fast and safe.

### SUMMARY

Exemplary embodiments of the invention provide devices and methods for de-energizing a PV system. According to an aspect of the invention, a method includes detecting a resistance between a first photovoltaic unit and ground, wherein the first photovoltaic unit is connected to at least one additional photovoltaic unit. If the resistance is less than a threshold, the first photovoltaic unit is shorted by connecting a positive conductor of the first photovoltaic unit with a negative conductor of the first photovoltaic unit. Shorting the first photovoltaic unit causes the at least one additional photovoltaic unit to detect the resistance that is less than the threshold, thereby shorting the at least one additional photovoltaic unit by connecting a positive conductor of the at least one additional photovoltaic unit with a negative conductor of the at least one additional photovoltaic unit.

The resistance that is less than the threshold may be caused by a failure of the first photovoltaic unit. For example, the failure may be caused by conductor damage within the first photovoltaic unit.

Alternatively, the resistance that is less than the threshold may be caused by opening a grounding DC disconnect switch, thereby grounding the negative conductor of the first photovoltaic unit. The grounding DC disconnect switch may be arranged between the first photovoltaic unit and an inverter of a photovoltaic system.

The method may also include detecting a voltage across the first photovoltaic unit. If the voltage is less than zero, the first photovoltaic unit is shorted by connecting the positive conductor of the first photovoltaic unit with the negative conductor of the first photovoltaic unit. The voltage that is less than zero may be caused by at least partial shading of the first photovoltaic unit.

The method may also include detecting a voltage across a first cell or a first group of cells within the first photovoltaic unit. If the voltage is less than zero, the first cell or the first group of cells is shorted by connecting a positive conductor of the first cell or the first group of cells with a negative conductor of the first cell or the first group of cells.

According to another aspect of the invention, a system is provided. The system includes a first photovoltaic unit having a first detection unit, and a second photovoltaic unit having a second detection unit. The first detection unit includes a first sensor that is configured to detect a first resistance between the first photovoltaic unit and ground. The second detection unit includes a second sensor that is configured to detect a second resistance between the second photovoltaic unit and ground. If the first resistance detected by the first sensor is less than a threshold, the first detection unit sends a first signal to connect a positive conductor of the first photovoltaic unit with a negative conductor of the first photovoltaic unit, thereby shorting the first photovoltaic unit. Shorting the first photovoltaic unit causes the second resistance detected by the second sensor to become equal to the first resistance, such that the second detection unit sends a second signal to connect a positive conductor of the second photovoltaic unit with a negative conductor of the second photovoltaic unit, thereby shorting the second photovoltaic unit.

The first detection unit may also include at least one switch. The first signal may cause the at least one switch to close, thereby connecting the positive conductor of the first photovoltaic unit with the negative conductor of the first photovoltaic unit.

The first detection unit may also include a voltage sensor that is configured to detect a first voltage across a first cell or a first group of cells within the first photovoltaic unit. If the first voltage is less than zero, the first detection unit sends a third signal to connect a positive conductor of the first cell or the first group of cells with a negative conductor of the first cell or the first group of cells, thereby shorting the first cell or the first group of cells.

According to yet another aspect of the invention, another system is provided. The system includes a first photovoltaic unit that is connected to a first detection unit, and a second photovoltaic unit that is connected to a second detection unit. The first detection unit includes a first sensor that is configured to detect a first resistance between the first photovoltaic unit and ground, and the second detection unit includes a second sensor that is configured to detect a second resistance between the second photovoltaic unit and ground. If the first resistance detected by the first sensor is less than a threshold, the first detection unit sends a first signal to connect a positive conductor of the first photovoltaic unit with a negative conductor of the first photovoltaic unit, thereby shorting the first photovoltaic unit. Shorting the first photovoltaic unit causes the second resistance detected by the second sensor to become equal to the first resistance, such that the second detection unit sends a second signal to connect a positive conductor of the second photovoltaic unit with a negative conductor of the second photovoltaic unit, thereby shorting the second photovoltaic unit.

The first detection unit may also include a switch. The first signal causes the switch to close, thereby connecting the positive conductor of the first photovoltaic unit with the negative conductor of the first photovoltaic unit.

The first detection unit may also include a voltage sensor that is configured to detect a first voltage across the first photovoltaic unit. If the first voltage is less than zero, the first detection unit sends a third signal to connect the positive conductor of the first photovoltaic unit with the negative conductor of the first photovoltaic unit, thereby shorting the first photovoltaic unit.

According to a further aspect of the invention, a device is provided. The device includes a switch, a controller that is configured to control the switch, and a sensor that is configured to detect a resistance between a photovoltaic unit and ground. If the resistance detected by the sensor is less than a threshold, the controller closes the switch, thereby shorting the photovoltaic unit.

The device may also include a voltage sensor that is configured to detect a voltage across the photovoltaic unit. If the voltage detected by the voltage sensor is less than zero, the controller closes the switch, thereby shorting the photovoltaic unit.

Other objects, advantages, and novel features of the present invention will become apparent from the following detailed description of the invention when considered in conjunction with the accompanying drawings.

### BRIEF DESCRIPTION OF THE DRAWINGS

FIG. 1 depicts a PV system in which each of a plurality of isolation detection units (IDUs) is integrated within a respective PV unit;

FIG. 2 depicts another PV system in which each of a plurality of IDUs is provided as a standalone unit that is connected to a respective PV unit;

FIG. 3 depicts an IDU that is implemented inside the PV junction box of a PV module;

FIG. 4 depicts a circuit diagram for measuring isolation resistance;

FIG. 5 depicts a standalone IDU that is connected to a PV module; and

FIG. 6 depicts a flowchart of a method for de-energizing a PV system.

### DETAILED DESCRIPTION

Exemplary embodiments of the present invention provide Isolation Detection Units (IDUs) that may be used to de-energize a PV system, which includes a plurality of series-connected PV units, such as PV modules. Each IDU may continually detect the isolation resistance Rᵢₛₒ between one or more DC conductors of a respective PV module and the PV module frame ground. Alternatively, each IDU may detect the isolation resistance Rᵢₛₒ at suitable intervals, or when instructed by a user. If ground isolation is lost due to local failure of the PV module or intentional grounding of the system, the IDU short circuits the PV module to a safe terminal voltage, such as less than 1 V. This causes all of the series-connected PV modules to become de-energized, as described in further detail below.

Historically, PV systems in the United States were grounded by connecting one PV conductor (typically the negative conductor) to ground at the inverter. This follows the convention of AC circuits, where one conductor is at ground potential while one or more other conductors are “hot.” Recently however, the US electrical code has migrated to a situation where ungrounded PV systems are allowed and even encouraged. In this situation, neither the positive DC conductor nor the negative DC conductor is directly connected to ground. The required isolation resistance Rᵢₛₒ between the inverter DC input and ground is specified by various standards as Rᵢₛₒ>500 kΩ or Rᵢₛₒ=2000 kΩ/P_{DC}_{_}_{inverter [kW]}. Also, for an individual module, the specified module-level isolation resistance Rᵢₛₒ between the module leads and the metal ground frame is specified by another standard as Rᵢₛₒ>40 MΩ/m² surface area. For a typical 1.5 m² module, this value is Rᵢₛₒ>27 MΩ.

In either case, the isolation resistance Rᵢₛₒ required for system operation is very high. Exemplary embodiments of the present invention use the isolation resistance Rᵢₛₒ as a sensitivity value for detecting a loss in ground isolation at the energized terminals of the PV module. Specifically, as discussed in further detail below, local module-level detection of loss of ground isolation, as indicated by a low value of the isolation resistance Rᵢₛₒ, results in a module-level disconnect of the PV system.

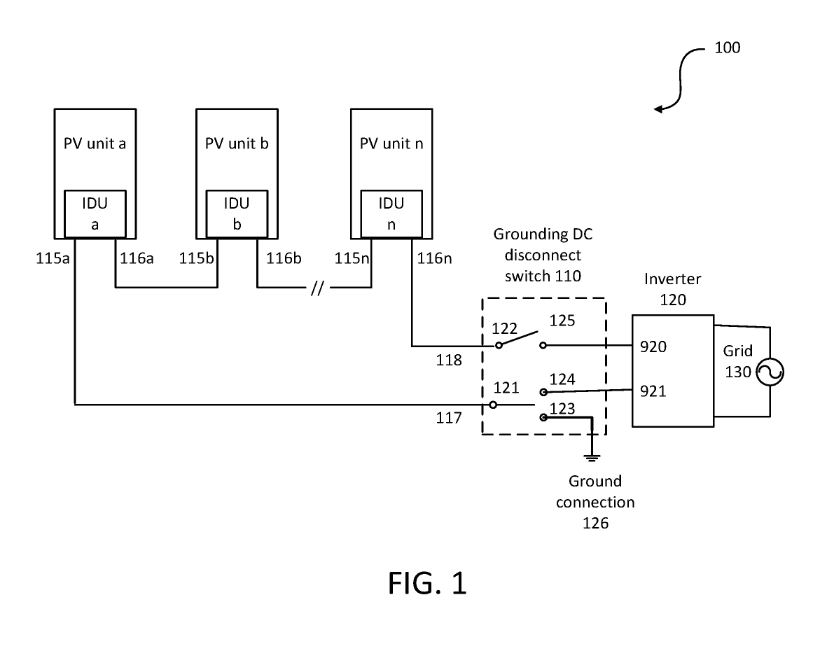

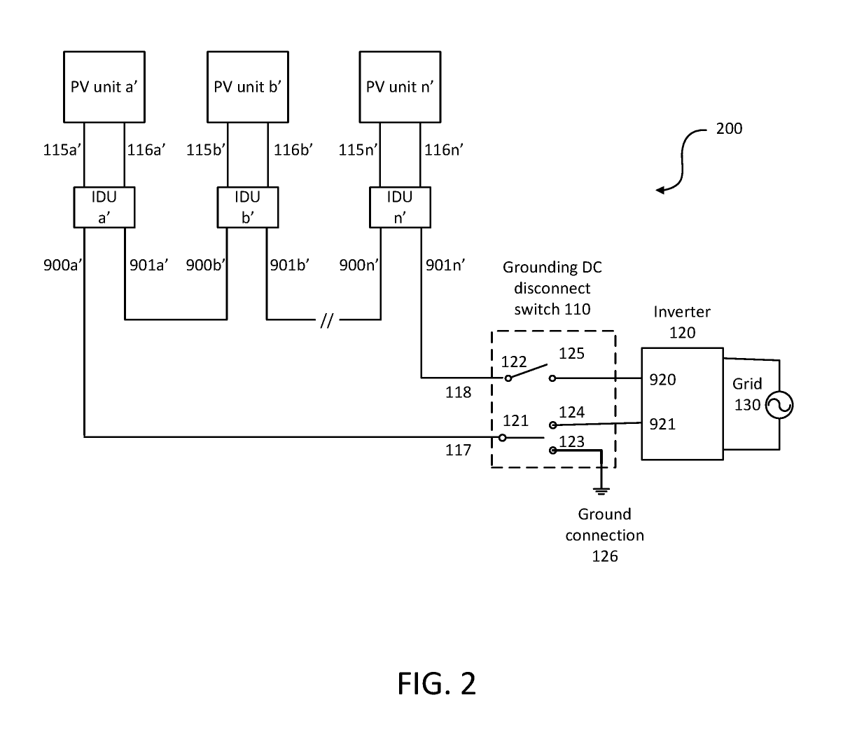

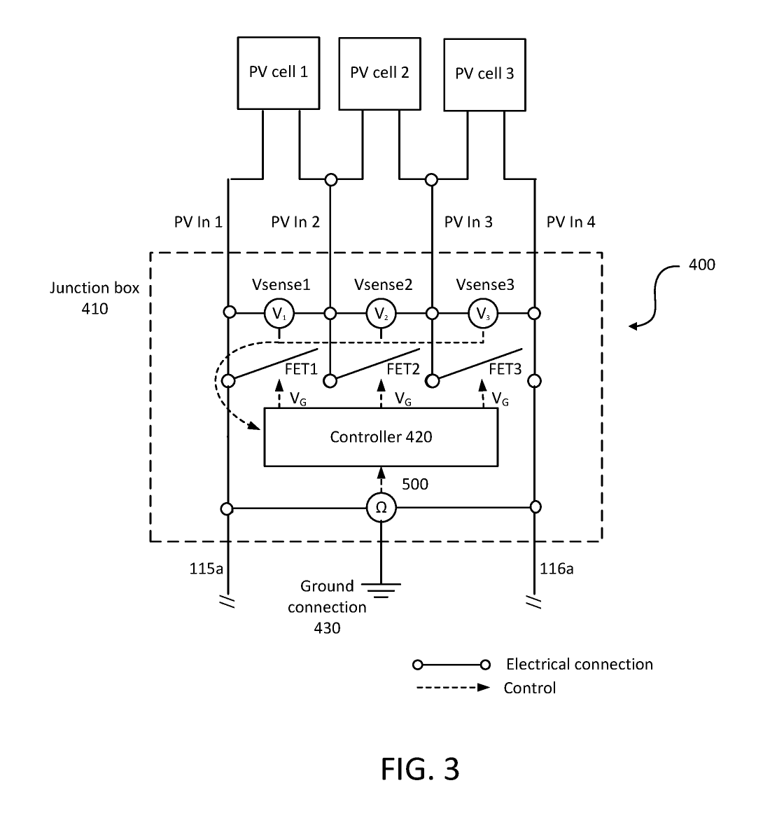

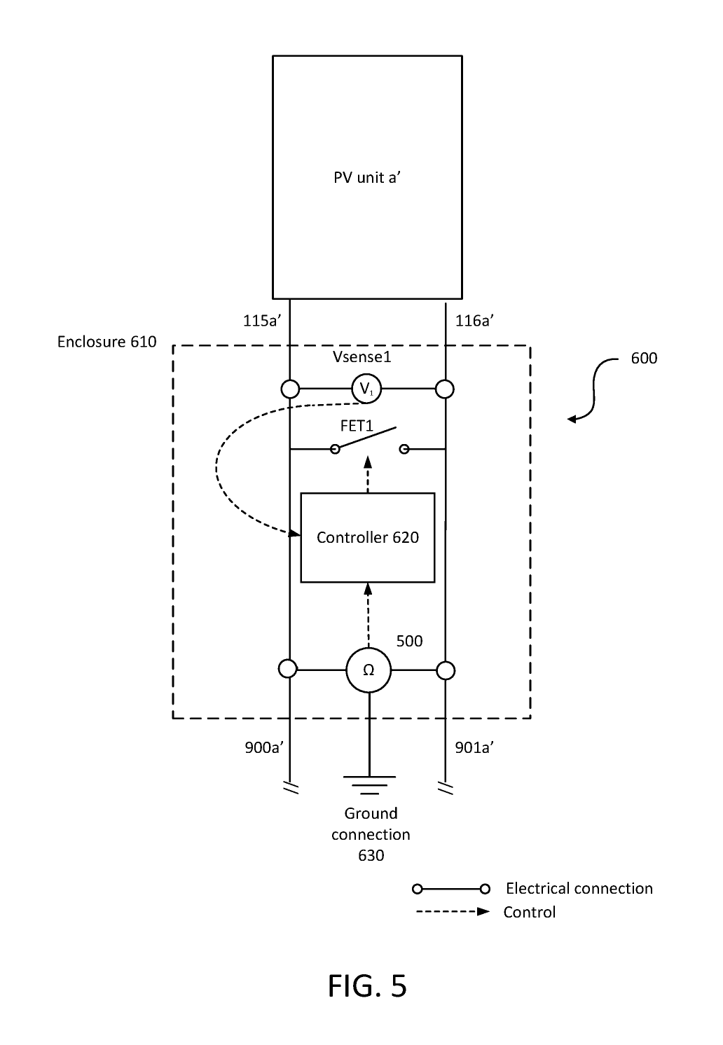

FIGS. 1 and 2 show examples of different ways in which the IDUs may be incorporated into a PV system. FIG. 1 shows a PV system 100 in which each of a plurality of IDUs a, b, . . . , n is integrated within a respective PV unit a, b, . . . , n. Each PV unit a, b, . . . , n is typically a PV module, but may be any other type of PV unit, such as a PV cell, a PV panel, or a PV array. As discussed below in further detail with reference to FIG. 3, each IDU may be connected in series with the terminals of a PV module within an existing PV module junction box, which has a direct electrical connection to the PV bus bar foil. FIG. 2 shows another PV system 200 in which each of a plurality of IDUs a′, b′, . . . , n′ is provided as a standalone unit that is connected to a respective PV unit a′, b′, . . . , n′. As discussed below in further detail with reference to FIG. 5, the plurality of IDUs a′, b′, . . . , n′ may be connected with the PV units a′, b′, . . . , n′ via existing cabling in the PV units a′, b′, . . . , n′.

As discussed in further detail below, in the systems shown in FIGS. 1 and 2, if one IDU detects an isolation resistance Rᵢₛₒ below a threshold, the IDU shorts its respective PV unit by connecting a positive conductor of the PV unit with a negative conductor of the PV unit. The threshold may be any suitable value that is below the required isolation resistance Rᵢₛₒ discussed above. For example, the threshold may be 1 kΩ, or any other suitable value. The low isolation resistance Rᵢₛₒ may be caused by a failure of the PV unit. For example, the failure may be caused by conductor damage within the PV unit.

If one PV unit is shorted by the method discussed above, the remaining series-connected PV units within the PV system will also be shorted, such that the entire PV system is de-energized. For example, referring to the PV system 100 shown in FIG. 1, if PV unit a suffers conductor damage that causes a failure, IDU a detects an isolation resistance Rᵢₛₒ that is less than the threshold. IDU a then sends a signal to short PV unit a by connecting a positive DC output conductor 116a of PV unit a with a negative DC output conductor 115a of PV unit a. The next IDU in series (IDU b) then sees the same low isolation resistance Rᵢₛₒ, and sends a signal to short PV unit b. This cascade effect continues until PV unit n has been shorted. The PV system may be re-energized by fixing PV unit a such that IDU a no longer detects the low isolation resistance Rᵢₛₒ. A similar effect is provided in the PV system 200 shown in FIG. 2.

Alternatively, the low isolation resistance Rᵢₛₒ may be caused by intentionally opening a grounding DC disconnect switch 110. This would enable firefighters to de-energize the PV system in case of an emergency. As shown in FIG. 1, PV unit a has DC output conductors 115a and 116a. Similarly, PV unit b has DC output conductors 115b and 116b, and PV unit n has DC output conductors 115n and 116n. In this example, DC output conductor 116a of PV unit a is connected in series with DC output connector 115b of PV unit b. The series connections between the PV units a, b, . . . , n continue, such that the DC output connector 116n terminates at the grounding DC disconnect switch 110 that feeds into the inverter 120. The DC output conductor 115a also terminates at the grounding DC disconnect switch 110. The lowest negative DC output conductor 115a and the highest positive DC output conductor 116n are extended to the grounding DC disconnect switch 110 as negative DC home run conductor 117 and positive DC home run conductor 118, respectively.

Similarly, as depicted in FIG. 2, PV unit a′ has DC output conductors 115a′ and 116a′ that are connected as inputs to IDU a′, PV unit b′ has DC output conductors 115b′ and 116b′ that are connected as inputs to IDU b′, and PV unit n′ has DC output conductors 115n′ and 116n′ that are connected as inputs to IDU n′. Further, IDU a′ has DC output conductors 900a′ and 901a′, IDU b′ has DC output conductors 900b′ and 901b′, and IDU n′ has DC output conductors 900n′ and 901n′. DC output conductor 901a‘ of IDU a’ is connected in series with DC output connector 900b‘ of IDU b’. The series connections between the IDUs a′, b′, . . . , n′ continue, such that the DC output connector 901n′ terminates at the grounding DC disconnect switch 110 that feeds into the inverter 120. The DC output conductor 900a′ also terminates at the grounding DC disconnect switch 110. The lowest negative DC output conductor 900a′ and the highest positive DC output conductor 901n′ are extended to the grounding DC disconnect switch 110 as negative DC home run conductor 117 and positive DC home run conductor 118, respectively.

As depicted in FIGS. 1 and 2, both DC home run conductors 117 and 118 are connected to the grounding DC disconnect switch 110, which differs from a related art double-pole, single-throw (two element) DC disconnect switch that is typically found in a PV electrical assembly. In this example, the grounding DC disconnect switch 110 can be described as a double-pole, double-throw (DPDT) switch with two input terminals 121 and 122 and three output terminals 123, 124, and 125. The left-hand side of the input terminal 122 is connected to the positive DC home run conductor 118. The right-hand side of the input terminal 122 is either connected to a positive DC input 920 of the inverter 120 via the output terminal 125, or is unconnected. The left-hand side of the input terminal 121 is connected to the negative home run conductor 117. The right-hand side of the input terminal 121 is either connected to a negative DC input 921 of the inverter 120 via output terminal 124, or connected to a ground connection 126 via output terminal 123.

When opened, the grounding DC disconnect switch 110 disconnects the DC home run conductors 117 and 118 from the DC inputs 921 and 920 of the inverter 120, respectively, and simultaneously connects the negative DC home run conductor 117 to a ground connection 126 through a low-impedance (<10Ω) output terminal 123. Although either or both of the DC home run conductors 117 and 118 could be grounded, grounding only the negative DC home run conductor 117 may be the safest option, because otherwise there is the potential for the entire array to be shorted together across the hard short-circuit created by the grounding DC disconnect switch 110. This could result in high current, arcing, and/or failure of the grounding DC disconnect switch 110. In contrast, grounding only the DC home run conductor 117 will not result in any current draw, since there is no direct current path between the negative DC home run conductor 117 and the positive DC home run conductor 118.

Accordingly, the grounding DC disconnect switch 110 may be opened in an emergency situation to cause each of the IDU units a-n shown in FIG. 1 (or the IDU units a′-n′ shown in FIG. 2) to see the low isolation resistance Rᵢₛₒ. The PV system may be returned to normal operations by closing the grounding DC disconnect switch 110, such that the DC home run conductors 117 and 118 are connected to the inverter 120 to enable PV energy export to the grid 130. As discussed above, the ground connection 126 of the grounding DC disconnect switch 110 can be applied on either the positive DC home run conductor 118 or the negative DC home run conductor 117. A grounded terminal could also be applied to both the positive DC home run conductor 118 and the negative DC home run conductor 117, if the grounding DC disconnect switch 110 is sufficiently rated for the short circuit current that would result across the input terminals 121 and 122.

As an alternative to the manual operation of the grounding DC disconnect switch 110 discussed above, the grounding DC disconnect switch 110 may be automatically operated. For example, this could be achieved by a command to close from the inverter 120, a loss of the connection to the grid 130, a loss of a keep-alive signal originating from the inverter 120 or another source, or any other signal that instructs the grounding DC disconnect switch 110 to close.

FIG. 3 shows an example of an IDU 400 that may be directly implemented inside a junction box 410 of a PV unit, such as a PV module. This IDU 400 may be implemented as IDU a, IDU b, and/or IDU n in the PV system 100 shown in FIG. 1. A typical junction box has positive and negative connections entering it from a number of series-connected PV cells or groups of PV cells within the PV module. In this example, four separate electrical connections PV In 1-PV In 4 enter the junction box 410 from three series-connected PV cells PV cell 1, PV cell 2, and PV cell 3 within the PV module. Here, PV In 1 is connected to the negative terminal of the negative-most PV cell (PV cell 1) within the series string, and PV In 4 is connected to the positive terminal of the positive-most PV cell (PV cell 3) within the series string. Two additional intermediate terminal connections PV In 2 and PV In 3 are also present, representing a common positive/negative connection point at two locations within the series string. In this example, PV In 2 is connected at a point 1/3 of the way up the series string between PV cell 1 and PV cell 2, and PV In 3 is connected at a point 2/3 of the way up the series string between PV cell 2 and PV cell 3. Although each PV cell 1, 2, and 3 is shown as an individual PV cell, one or more of the PV cells 1, 2, and 3 may instead include a group of PV cells. Further, any number of PV cells or groups of PV cells may be used, provided that x number of connections are available for x−1 number of PV cells or groups of PV cells.

Further, as shown in FIG. 3, two DC output conductors 115a and 116a are present at the output side of the IDU 400. These provide an external connection to enable the PV-produced energy to be exported from the PV module. DC output conductor 115a is directly connected to PV In 1, and DC output conductor 116a is directly connected to PV In 4.

The IDU 400 may include three MOSFET switches FET1, FET2, and FET3. Each of the MOSFET switches FET1, FET2, and FET3 may take the place of a traditional backplane bypass diode, and may provide reverse-bias protection and emergency disconnect capability according to exemplary embodiments of the present invention. A MOSFET is an electronic switch that has a controllable source-drain resistance, with values between close-circuit (<1Ω) and open-circuit (>1 MΩ). The source-drain resistance value may be controlled by applying a specific bias voltage to the gate of the MOSFET. As shown in FIG. 3, each MOSFET switch FET1, FET2, and FET3 is connected across a respective one of the PV cells 1, 2, or 3 via two of the PV input terminals, and has a low on-resistance to limit the forward voltage drop while conducting. Each MOSFET switch FET1, FET2, and FET3 operates in either open-circuit (normal operation) or close-circuit (emergency operation) conditions, as dictated by a controller 420. Under open-circuit operation, there is no current flowing through the MOSFET switches FET1, FET2, and FET3, and power is exported normally by the PV module through the DC output conductors 115a and 116a. In contrast, under close-circuit conditions, current generated by the PV cells 1, 2, and 3 is instead diverted through the MOSFET switches FET1, FET2, and FET3, resulting in the voltage across the corresponding DC output conductors 115a and 116a dropping to near zero.

The controller 420 is used to drive each MOSFET switch FET1, FET2, and FET3 by providing a gate voltage V_{G} to operate the respective MOSFET switch in either open-circuit or close-circuit condition. The determination of whether the controller 420 operates one of the MOSFET switches FET1, FET2, or FET3 in open-circuit or close-circuit condition may be based on its monitoring of an isolation resistance Rᵢₛₒ sensor 500, as well as multiple voltage sensors Vsense1, Vsense2, and Vsense3.

The isolation resistance Rᵢₛₒ may be detected by any suitable method. For example, the isolation resistance Rᵢₛₒ sensor 500 may detect the electrical resistance between one of the DC output conductors 115a or 116a and the metallic frame of the PV module, which is typically connected to ground through the ground connection 430 shown in FIG. 3. Alternatively, for frameless modules, the isolation resistance Rᵢₛₒ may be detected between one of the DC output conductors 115a or 116a and the system ground potential. The isolation resistance Rᵢₛₒ sensor 500 may use a wired connection between the PV module frame and the PV junction box 410 in order to measure this isolation resistance Rᵢₛₒ. This is because the PV module junction box 410 may be separated from the module frame by several inches.

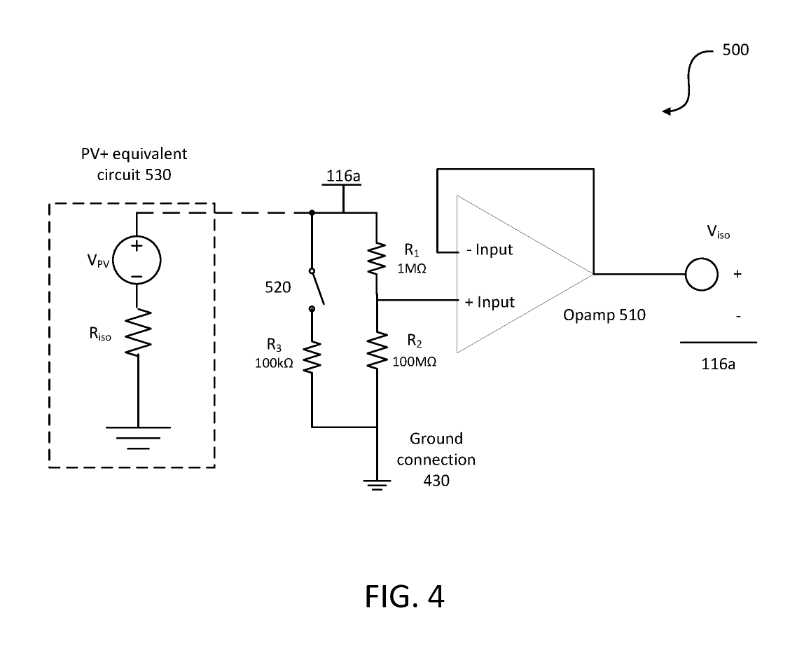

An example of a circuit implementation of the isolation resistance Rᵢₛₒ sensor 500 is shown in FIG. 4. In this example, an operational amplifier (opamp) 510 is used to detect the voltage between the DC output conductor 116a and the ground connection 430. This voltage is measured across voltage divider resistors R₁ and R₂. In this example, the voltage divider resistors R₁ and R₂ are set to values of 1 MΩ and 100 MΩ, respectively. However, the voltage divider resistors R₁ and R₂ may be set to any appropriate values. The inverting opamp input (−Input) is connected to the output of the opamp 510 directly, thereby generating an output voltage Vᵢₛₒ equal to the voltage at the + Input terminal in a unity gain configuration. A switch 520 may be used to reconfigure the voltage divider to include the voltage divider resistor R₃. In this example, R₃ is set to 100 kΩ, but may be set to any appropriate value. The value of the voltage divider resistor R₃ corresponds to the threshold to which the isolation resistance Rᵢₛₒ is compared.

As depicted in FIG. 4, the DC output conductor 116a may be represented by a PV+ equivalent circuit 530 having a voltage V_{PV} and an isolation resistance Rᵢₛₒ with respect to ground. According to circuit analysis, the isolation resistance Rᵢₛₒ may be calculated by monitoring the change in the output voltage Vᵢₛₒ following the closing of the switch 520. For the limiting case in which Rᵢₛₒ=0 S, indicating a hard short circuit between ground and the DC output conductor 116a, the output voltage Vᵢₛₒ is unchanged. For the opposite limiting case in which Rᵢₛₒ>>R₃, switching the voltage divider resistor R₃ into the circuit by closing the switch 520 will result in a large change in the output voltage Vᵢₛₒ. Therefore, comparing the output voltage Vᵢₛₒ during operation of the switch 520 with the output voltage Vᵢₛₒ while the switch 520 is disconnected enables one to distinguish between an isolation resistance Rᵢₛₒ that is below the threshold and an isolation resistance Rᵢₛₒ that is above the threshold. For the resistor values chosen for the example shown in FIG. 4, the sensitivity of the isolation resistance Rᵢₛₒ sensor 500 is around 1 MΩ/V, such that a difference in the output voltage Vᵢₛₒ of 0.1 V during operation of the switch 520 (as compared with the output voltage Vᵢₛₒ when the switch 520 is disconnected) indicates a measured Rᵢₛₒ on the order of 100 kΩ.

Accordingly, if the change in the output voltage Vᵢₛₒ detected by the controller 420 is below 0.1 V, then the isolation resistance Rᵢₛₒ from the DC output conductor 116a to ground is below the threshold R₃ (100 kΩ in this example). This causes the controller 420 to generate a gate drive signal V_{G} that is sufficient to command all of the MOSFET switches FET1, FET2, and FET3 to close, thus connecting the DC output conductors 115a and 116a. This close-circuit condition of all the MOSFET switches FET1, FET2, and FET3 may occur during intentional emergency shorting of the PV system 400 using the grounding DC disconnect switch 110 of FIGS. 1 and 2, or if an unintentional ground-fault condition such as PV conductor damage occurs within one of the PV modules. In either case, the MOSFET switches FET1, FET2, and FET3 engage, rendering the PV module in a low-voltage, safe condition.

As depicted in FIG. 3, the voltage sensors Vsense1, Vsense2, and Vsense3 detect operating voltages V₁, V₂, and V₃ of respective series-connected PV cells 1, 2, and 3 within the PV module, and are present between respective pairs of PV electrical connections PV In 1 and PV In 2, PV In 2 and PV In 3, and PV In 3 and PV In 4. Under typical operation, the operating voltages V₁, V₂, and V₃ remain positive, between 0 V and the full open-circuit voltages of the respective series-connected PV cells 1, 2, and 3, typically around 20-24 V. However, under fault or partial shading conditions, the operating voltages V₁, V₂, and V₃ can be negative, which is a potentially damaging operating condition. Under such an operating condition, the relevant voltage sensor Vsense1, Vsense2, or Vsense3 sends an appropriate signal to the controller 420, which then generates a gate drive signal V_{G} sufficient to command the respective MOSFET switch FET1, FET2, or FET3 to operate in a close-circuit condition. This limits the potentially damaging negative voltage within the PV module by shorting the respective section of the PV module through the respective MOSFET. Although three voltage sensors Vsense1, Vsense2, and Vsense3 are shown in FIG. 3, any suitable number of voltage sensors may be used, based on the number of PV cells or groups of PV cells within the PV module.

Additionally, due to the potential interaction between the circuitry of the IDU 400 and the inverter 120, the voltage sensors Vsense1, Vsense2, and Vsense3 may also be used to ensure that each of the operating voltages V₁, V₂ and V₃ of the series-connected PV cells 1, 2, and 3 is above a threshold voltage Vₕᵢ. The threshold voltage Vₕᵢ may be set to any appropriate value, such as 5% below the open circuit voltage, to ensure that the PV module is not exporting power to the grid 130 when the shutdown functionality is enabled. This functionality is discussed in further detail below.

FIG. 5 shows an example of a standalone IDU 600 that may be connected to a respective PV unit, such as a PV module. This IDU 600 may be implemented in the PV system 200 shown in FIG. 2, and may be used as a retrofit to an existing PV system. For example, the IDU 600 may be used as IDU a′, which is connected to PV unit a′. As shown in FIG. 5, the IDU 600 is connected to the PV unit a′ by the DC output conductors 115a′ and 116a′. The isolation resistance Rᵢₛₒ sensor 500 may detect the electrical resistance between one of the DC output conductors 115a′ or 116a′ and the metallic frame of the PV module, which is wired to the ground connection 630 of the IDU 600.

The controller 620 controls a single module-level MOSFET switch FET1 to short-circuit the PV unit a′ if the isolation resistance Rᵢₛₒ sensor 500 detects a low isolation resistance Rᵢₛₒ from the PV terminal to ground, such as less than 1 kΩ. In this event, the MOSFET switch FET1 closes, such that the DC output conductors 115a′ and 116a′ of the PV unit a′ are connected together. Further, similar to the embodiment discussed above, the voltage sensor Vsense1 may be used to detect whether the operating voltage V₁ of the PV unit a′ is above the threshold voltage Vₕᵢ, indicating that the PV unit a′ is at or near open circuit. For the IDU 600, there may be a single voltage sensor Vsense1, if the local reverse bias protection of the PV module is not required for this embodiment.

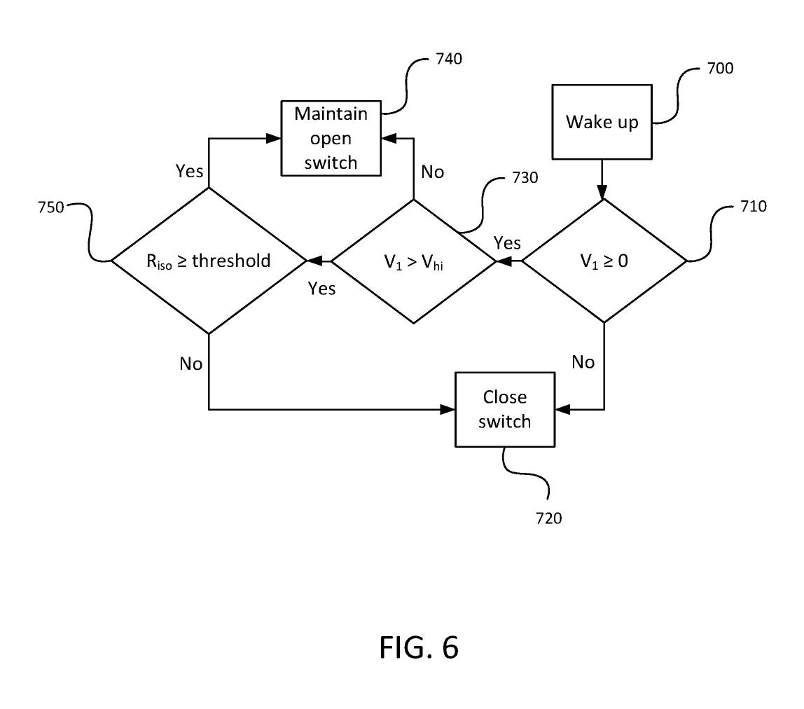

FIG. 6 shows a flowchart of a method for de-energizing a PV system according to exemplary embodiments of the present invention. This method may be implemented using the embodiment shown in FIGS. 1 and 3, or the embodiment shown in FIGS. 2 and 5. Before beginning the method shown in FIG. 6, the MOSFET switches FET1, FET2, and FET3 shown in FIG. 4 are open, and the MOSFET switch FET1 shown in FIG. 5 is open, such that PV energy can be exported to the grid 130.

After the system is activated at 700, the operating voltage V₁ of PV cell 1 within PV unit a may be monitored by the voltage sensor Vsense1 shown in FIG. 3. For simplicity, FIG. 6 only shows the flowchart for this single voltage sensor Vsense1. However, each voltage sensor within an IDU may perform a similar function. For the embodiment shown in FIGS. 1 and 3, this function may be performed by the voltage sensors Vsense1, Vsense2, and Vsense3 within the IDUs that are integrated into the respective PV units. For the embodiment shown in FIGS. 2 and 5, this function may be performed by the voltage sensors Vsense1 within the IDUs that are connected to the respective PV units. Alternatively, the method may proceed directly to 750 without performing 710 and/or 730.

As depicted in FIG. 6, if the operating voltage V₁ detected by the voltage sensor Vsense1 is less than 0 V at 710, the corresponding MOSFET switch FET1 within the IDU is closed at 720, thereby shorting that portion of the corresponding PV unit. On the other hand, if the operating voltage V₁ detected by the voltage sensor Vsense1 is greater than or equal to 0 V at 710, the IDU may compare the operating voltage V₁ with the threshold voltage Vₕᵢ at 730. If the operating voltage V₁ is greater than the threshold voltage Vₕᵢ, the IDU proceeds with detecting the isolation resistance Rᵢₛₒ at 750 without the risk of undesired interaction with the inverter 120. On the other hand, if the operating voltage V₁ is less than or equal to the threshold voltage Vₕᵢ, the MOSFET switch FET1 within the IDU remains open at 740.

The IDU then uses its isolation resistance Rᵢₛₒ sensor 500 to monitor the isolation resistance Rᵢₛₒ between its respective PV unit and ground. At 750, if the IDU detects an isolation resistance Rᵢₛₒ below a threshold, such as 1 kΩ, the IDU shorts its respective PV unit by connecting a positive conductor of the PV unit with a negative conductor of the PV unit. This is achieved by closing all of the switches within the IDU at 720. For example, the MOSFET switches FET1, FET2, and FET3 shown in FIG. 3 are closed, such that the DC output conductor 115a is connected with the DC output conductor 116a. In another example, the MOSFET switch FET1 shown in FIG. 5 is closed, such that the DC output conductor 115a′ is connected with the DC output conductor 116a′. Once that PV unit has been shorted, the next IDU detects the isolation resistance Rᵢₛₒ below the threshold, causing the next IDU to short its respective PV unit. This may continue until all of the series-connected PV units have been shorted, such that there is no live circuit in the system. On the other hand, if the isolation resistance Rᵢₛₒ is above the threshold at 750, the switch or switches within the IDU remain open at 740.

In additional embodiments, the IDU functionality may be implemented within a different module-level power electronics device, such as a DC-AC microinverter or a DC-DC power optimizer. These devices typically use another signal to turn off, such as a lack of AC grid voltage or a wireless emergency disconnect signal. However, these devices could instead rely on a signal from the IDU functionality described above.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method comprising:
detecting a resistance between a first photovoltaic unit and ground, wherein the first photovoltaic unit is connected to at least one additional photovoltaic unit; and
if the resistance is less than a threshold, shorting the first photovoltaic unit by connecting a positive conductor of the first photovoltaic unit with a negative conductor of the first photovoltaic unit,
wherein shorting the first photovoltaic unit causes the at least one additional photovoltaic unit to detect the resistance that is less than the threshold, thereby shorting the at least one additional photovoltaic unit by connecting a positive conductor of the at least one additional photovoltaic unit with a negative conductor of the at least one additional photovoltaic unit.

2. The method according to claim 1, wherein the resistance that is less than the threshold is caused by a failure of the first photovoltaic unit.

3. The method according to claim 2, wherein the failure is caused by conductor damage within the first photovoltaic unit.

4. The method according to claim 1, wherein the resistance that is less than the threshold is caused by opening a grounding DC disconnect switch, thereby grounding the negative conductor of the first photovoltaic unit.

5. The method according to claim 4, wherein the grounding DC disconnect switch is arranged between the first photovoltaic unit and an inverter of a photovoltaic system.

6. The method according to claim 1, further comprising:
detecting a voltage across the first photovoltaic unit; and
if the voltage is less than zero, shorting the first photovoltaic unit by connecting the positive conductor of the first photovoltaic unit with the negative conductor of the first photovoltaic unit.

7. The method according to claim 6, wherein the voltage that is less than zero is caused by at least partial shading of the first photovoltaic unit.

8. The method according to claim 1, further comprising:
detecting a voltage across a first cell or a first group of cells within the first photovoltaic unit; and
if the voltage is less than zero, shorting the first cell or the first group of cells by connecting a positive conductor of the first cell or the first group of cells with a negative conductor of the first cell or the first group of cells.

9. A system comprising:
a first photovoltaic unit comprising a first detection unit; and
a second photovoltaic unit comprising a second detection unit; wherein:
the first detection unit comprises a first sensor that is configured to detect a first resistance between the first photovoltaic unit and ground,
the second detection unit comprises a second sensor that is configured to detect a second resistance between the second photovoltaic unit and ground,
if the first resistance detected by the first sensor is less than a threshold, the first detection unit sends a first signal to connect a positive conductor of the first photovoltaic unit with a negative conductor of the first photovoltaic unit, thereby shorting the first photovoltaic unit, and
shorting the first photovoltaic unit causes the second resistance detected by the second sensor to become equal to the first resistance, such that the second detection unit sends a second signal to connect a positive conductor of the second photovoltaic unit with a negative conductor of the second photovoltaic unit, thereby shorting the second photovoltaic unit.

10. The system of claim 9, wherein:
the first detection unit further comprises at least one switch, and
the first signal causes the at least one switch to close, thereby connecting the positive conductor of the first photovoltaic unit with the negative conductor of the first photovoltaic unit.

11. The system of claim 9, wherein:
the first detection unit further comprises a voltage sensor that is configured to detect a first voltage across a first cell or a first group of cells within the first photovoltaic unit, and
if the first voltage is less than zero, the first detection unit sends a third signal to connect a positive conductor of the first cell or the first group of cells with a negative conductor of the first cell or the first group of cells, thereby shorting the first cell or the first group of cells.

12. A system comprising:
a first photovoltaic unit that is connected to a first detection unit; and
a second photovoltaic unit that is connected to a second detection unit; wherein:
the first detection unit comprises a first sensor that is configured to detect a first resistance between the first photovoltaic unit and ground,
the second detection unit comprises a second sensor that is configured to detect a second resistance between the second photovoltaic unit and ground,
if the first resistance detected by the first sensor is less than a threshold, the first detection unit sends a first signal to connect a positive conductor of the first photovoltaic unit with a negative conductor of the first photovoltaic unit, thereby shorting the first photovoltaic unit, and
shorting the first photovoltaic unit causes the second resistance detected by the second sensor to become equal to the first resistance, such that the second detection unit sends a second signal to connect a positive conductor of the second photovoltaic unit with a negative conductor of the second photovoltaic unit, thereby shorting the second photovoltaic unit.

13. The system of claim 12, wherein:
the first detection unit further comprises a switch, and
the first signal causes the switch to close, thereby connecting the positive conductor of the first photovoltaic unit with the negative conductor of the first photovoltaic unit.

14. The system of claim 12, wherein:
the first detection unit further comprises a voltage sensor that is configured to detect a first voltage across the first photovoltaic unit, and
if the first voltage is less than zero, the first detection unit sends a third signal to connect the positive conductor of the first photovoltaic unit with the negative conductor of the first photovoltaic unit, thereby shorting the first photovoltaic unit.

15. A device comprising:
a switch;
a controller that is configured to control the switch; and
a sensor that is configured to detect a resistance between a photovoltaic unit and ground;
wherein if the resistance detected by the sensor is less than a threshold, the controller closes the switch, thereby shorting the photovoltaic unit.

16. The device of claim 15, further comprising:
a voltage sensor that is configured to detect a voltage across the photovoltaic unit,
wherein if the voltage detected by the voltage sensor is less than zero, the controller closes the switch, thereby shorting the photovoltaic unit.
